(19) United States
(12) Patent Application Publication
(10) Pub. No.: US 2025/0319632 A1
(43) Pub. Date: Oct. 16, 2025

(54) Method and Device for Separating Multilayer Composite Materials

(71) Applicants: Wolfram Palitzsch, Freiberg (DE); Ingo Röver, Freiberg (DE)

(72) Inventors: Wolfram Palitzsch, Freiberg (DE); Ingo Röver, Freiberg (DE)

(21) Appl. No.: 18/562,910

(22) PCT Filed: Apr. 14, 2022
(86) PCT No.: PCT/DE2022/100292

§ 371 Date: Nov. 21, 2023

(30) Foreign Application Priority Data
Apr. 16, 2021 (DE) 102021109591.3

(51) Int. Cl. B29B 17/02; B29B 17/04

(52) U.S. Cl. CPC B29B 17/02; B29B 17/04; B29B 2017/0428

(57) ABSTRACT

The invention relates to a method and a device for separating multilayer composite material in which valuable material is located between two layers of the multilayer composite material, in particular in the form of photovoltaic modules (PV), TFT, OLED, or LCD displays, consisting of at least one lower hard layer (1) and at least one soft layer (2, 3) located thereon, wherein one or more layers of the multilayer composite material to be separated is cut in layers or as a whole using at least one high-pressure water jet and is then raised and individualized, and one or more nozzles which discharge the high-pressure water jet are rotated by means of a rotatable nozzle head (DK) about a rotational axis (L) of the nozzle head (DK) while at the same time the nozzle head (DK) and the multilayer composite material are moved relative to each other such that the valuable materials lie freely individually or on the separated layers after the separation process. The device has at least one nozzle (D1, D2) for discharging at least one respective high-pressure water jet, and at least one nozzle head (DK) has a nozzle (DK) arranged outside of the rotational axis of the nozzle head (DK).

### CROSS REFERENCE TO RELATED APPLICATIONS

This application is the U.S. national stage of International Application No. PCT/DE2022/100292, filed on 2022 Apr. 14. The international application claims the priority of DE 102021109591.3 filed on 2021 Apr. 16; all applications are incorporated by reference herein in their entirety.

### BACKGROUND

The present invention relates to a method for separating composite materials or multilayer systems according to the preamble of the first claim, as well as a related device according to the preamble of claim 11.

Solar power systems, so-called tablet computers, smartphones, laptop screens, displays and products based on OLED (organic light-emitting diodes) are examples of electronic products in which multilayer technologies play a major role. A key common feature of these products is that they have a multilayer structure and often the relevant functional layers have been built up on a substrate carrier, e.g. glass, which has usually still been laminated with plastic films for protection or has further layers, such as various plastics, for example polarization films in TFT monitors. The functional layers can contain valuable chemical compounds of silicon, indium, gallium, arsenic, cadmium, tellurium, molybdenum, copper, silver, tin and/or selenium, but also special organic substances (e.g. liquid crystals), wherein the listed elements are often present as intermediates, such as compound semiconductors (gallium arsenide, cadmium telluride, etc.) or as conductive structures (molybdenum, indium tin oxide).

Indium, selenium, tellurium, gallium are elements that have to be imported almost completely in a country like Germany, which is poor in raw materials. The economic importance of recycling waste containing these substances, such as end-of-life photovoltaic modules and the associated reuse of these metals, is therefore now an important issue. However, the dissipative use of many special materials in countless products (photovoltaic modules, cell phones, flat screens, etc.) makes recycling difficult and only allows them to be returned to recycling loops to a certain extent.

In the course of the implementation of the Directive of the European Parliament and Council on Waste Electrical and Electronic Equipment (WEEE 2), corresponding amendments have been made at national level in the EU. The amended Waste Electrical and Electronic Equipment Directive of the European Union (WEEE, 2012/19/EU) was transposed into national law in Germany by the Electrical and Electronic Equipment Act (ElektroG). The new Electrical and Electronic Equipment Act came into force on Oct. 24, 2015, according to which photovoltaic modules, for example, fall under the scope of Category 4 “Consumer electronics equipment and photovoltaic modules”, which must now be recycled in accordance with the law. Recycling rates have been raised to 55 to 80% and recovery rates to 75 to 85%, depending on the category of equipment.

However, the recycling rate of 80% of the collected waste set by the legislator allows simple crushing and sorting processes to meet this requirement, assuming that a photovoltaic module consists of 95% glass. However, with this technology, all the other materials mentioned above, such as rare metals or silicon, are lost. The quality of the secondary glass obtained is far from sufficient for high-quality recycling, such as remelting in flat glass production. This in turn does not go hand in hand with already valid legal regulations, such as the current German recycling economy law (Kreislaufwirtschaftsgesetz), which is designed for a maximum possible quota for recycling. This generates additional interest in new economic and holistic recycling processes.

In addition to the economic aspect, the ecological aspect should not be neglected today. Looking at the ecotoxicity of the materials involved, it is noticeable that toxic elements, such as lead in photovoltaic modules, play a significant role, especially in the products used to date. At present, the prior art does not succeed in isolating the individual elements from the sandwich structures in an economically and ecologically optimal way; instead, they often disappear in low-quality products resulting from “downcycling” (such as silver in insulation materials like glass wool) or in slags or landfills. It is therefore all the more important to offer environmentally friendly recycling processes for production waste or defective or discarded products, which is the aim of the present invention.

Currently, photovoltaic waste is processed in the USA and Malaysia, and the process is described as very costly (U.S. Pat. No. 5,453,111). The actual separation problem is solved by shredding, creating many small sandwiches from one large one. Although chipping creates larger exposed areas, so that wet chemical processes are used to attack the semiconductors, the entire waste is treated in a shredded manner, which eventually leads to difficulties in the actual separation. Skimming plastic after warm nitric acid treatment of crushed modules is not a good economic and ecological solution. Likewise, thermal treatment (pyrolysis) as well as the removal of some metals in the gas phase (EP 1187224 B1) will not lead to a cost-effective process, because finally the entire waste volume (more than 90% glass) has to be heated up to pyrolysis temperature. On the one hand, this requires a very high energy input, and on the other hand, the use of further cooling steps is then additionally required in order to be able to further process the hot substrates in subsequent processes. In addition to the increased energy input for heating and cooling, a process-related long duration of the steps is also required, which in continuously running in-line systems can also result in a less favorable CO₂ footprint. An interesting and ecological approach can be found in a method exploiting the properties of nanoscale dispersions (DE 10 2011 000 322 A1), wherein the throughput depends on the speed of “infiltration” and one still has to eventually separate a mixture of materials in an expensive way. The approach of using laser technology, which is applied for edge deletion of thin-film photovoltaic products, for a recycling process (DE 10 2008 047 675 B4) also reveals a number of disadvantages upon closer examination. The high energy of the laser leads, for example, to the complete removal of the valuable layers or to damage to the substrate, i.e. in the worst case to the melting of the valuable layers into the substrate. An alternative application of flash lamps for silicon modules has also led to complications in trials, such as the decomposition of plastic and the associated occurrence of toxic gases, similar to conventional thermal processes, such as the treatment of substrates in ovens or by heating using halogen lamps or hot air, where as a rule the process time, which lasts several seconds to minutes, always leads to complete heating of the substrates, which does not appear to make sense in terms of energy.

According to the publication DE 19703104 A1, no layers of a multilayer composite material are separated from each other, but residual materials, which are produced during the production of data carrier disks, are removed from the data carrier disks such as D-ROMS, audio CDs or other disks.

The cleaning of polycarbonate is thus described, wherein residual materials (waste) present on the surface are removed from the surface of the polycarbonate.

The publication DE 44 40 483 A1 describes the large-area cleaning of a surface by means of a water jet and a rotating nozzle from which water jets pointing away from each other emerge. The cutting and lifting of layers of a multilayer composite is not feasible with this method and is also not being considered.

### SUMMARY

The present invention now relates to a method that can be applied in a versatile manner and a plant for the separation of multilayer systems, such as photovoltaic modules, without significantly heating the substrate or other materials, such as plastics or semiconductors.

The object of the present invention is therefore to provide a low-cost, elegant and low-energy and at the same time environmentally compatible method and a device for separating such composite systems or typical multilayer systems, as they occur in high-tech or green-tech waste or electrical and electronic waste, which avoids the disadvantages described and in particular does not lead to significant heating of the substrate or other materials, such as plastics or glass, does not generate losses due to ablation or evaporation, does NOT destroy the substrate or protective layers, such as glass, and thus allows easy access to the encapsulated valuable materials, such as valuable semiconductor materials or electrically conductive layers, in order to recycle them. At the same time, the main components of the multilayer system, such as front glass, individual plastic layers or plies, or other components should be individualized in order to also be able to sort them more easily and also feed them as valuable materials into a recycling process or further use.

This object is solved according to the invention by a method according to claim 1 and a device according to claim 9. Further advantageous embodiments are described in the subclaims.

### DETAILED DESCRIPTION

According to the method, for separating multilayer composite material, in particular in the form of photovoltaic modules (PV), TFT, OLED or LCD displays, consisting of at least one hard lower layer in the form of a carrier layer and at least one softer layer located thereon and to be separated from the carrier layer, one or more layers of the multilayer composite material to be separated are cut with at least one high-pressure water jet and lifted off and individualized, wherein one or more nozzles emitting the high-pressure water jet rotate about an axis of rotation (L) of the nozzle head (DK) by means of a rotatable nozzle head (DK), with simultaneous relative movement between the nozzle head (DK) and the multilayer composite material, so that, after separation, the valuable materials are exposed individually or on the separated layers and at least the valuable materials which were located between layers are recycled after separation.

With the method and the device according to the invention, valuable materials inside the multilayer composite material, which are located between layers of the multilayer composite material, such as semiconductor materials and/or metals, or also inorganic or organic materials, with which, for example, layers of a multilayer system can also be formed, can be made accessible to a targeted recycling technology after separation for the purpose of recycling.

After separation of the multilayer composite material, the valuable materials that were previously embedded between layers of the multilayer composite material are exposed individually or on the separated layers, so that at least the valuable materials can now be recycled after separation.

The rotation of the nozzle head with the at least one nozzle spaced from the axis of rotation causes the softer material of at least one other layer present on the lower layer in the form of the carrier layer to be separated and lifted off piece by piece.

Preferably, the separation method of the multilayer composite material (the separation of the at least one softer layer deposited on the lower layer from the lower harder layer in the form of the carrier layer) is carried out by at least two nozzles arranged in pairs cutting through one or more softer layers located above the lower hard carrier layer by rotation while simultaneously advancing the material to be treated or the nozzle head (DK) itself, and lifting off the cut sections and cleaning the lower layer at the same time.

In particular, the feed rate is designed in such a way that the layers of the material to be separated are each penetrated and, by means of a suitable jet angle (a) of the nozzles, this material is lifted from its substrate and thus loosened.

The pressure required for the destruction and thus the separation of the composite of the multilayer composite material is in particular between 750 and 3000 bar.

The rotational speed of the nozzle head (DK) is advantageously adapted to the respective feed rate in such a way that cutting and lifting for the respective number of individual layers (2, 3) takes place one after the other.

The individual further layers detached from the lower layer in the form of the carrier layer by the water jet(s) are rinsed off together by means of a water curtain from the walls of a blasting cabinet and washed out of a steel cabinet in a channel, for example.

Preferably, the waterjet treatment is carried out in strips according to the working width of the nozzle head, wherein the multilayer composite material to be treated is either scanned or, in the case of a linear pass, several nozzle heads are installed next to each other according to the width of the multilayer composite material to be treated.

The nozzle heads and the nozzles used therein will be adapted in particular with respect to A) jet shape, B) angle and C) number so that by A) the penetration depth, B) the lift-off and C) the working speed and/or the shape of the cut fragments can be adjusted.

According to the invention, the device for separating multilayer composite material, in particular in the form of photovoltaic modules (PV), TFT, OLED or LCD displays, consisting of at least one hard lower layer in the form of a carrier layer and at least one soft layer, has two nozzles for emitting at least one high-pressure water jet in each case, wherein the nozzles are arranged in such a way that the high-pressure water jets impinging on the surface of the multilayer composite material are spaced apart from one another.

Preferably, at least two nozzles are arranged in this case in a nozzle head rotatable about an axis of rotation, wherein the nozzle head is installed at a distance from the upper surface of the multilayer composite material which ensures a spacing of the water jets impinging on the upper surface of the multilayer composite material when the nozzles in the nozzle head are arranged inclined at an angle (a) to one another.

The multilayer composite materials to be separated, which consist in particular of a multilayer composite, are for example functional electronic components such as photovoltaic modules (PV), TFT, OLED or LCD displays.

The carrier layer in the form of the first layer consists, for example, of glass, metal, plastic (which is preferably harder than the material of the other layers on top of it) or ceramic. A combination of these materials is also possible for the lower layer in the form of the carrier layer.

The other layers on the carrier layer are preferably made of a material that is softer than the carrier layer (lower layer 1), for example EVA (ethylene vinyl acetate), polyvinyl fluoride (PVF), polyolefins, PET (polyethylene terephthalate).

The layers can also consist of several layers of the same or different aforementioned materials.

These further layers are present in particular as foils.

Materials/valuables embedded between the layers are, for example, semiconductor materials (e.g. silicon), functional materials or structures (e.g. semiconductor elements/silicon cells with their contacts, metals, or also inorganic or organic materials and also sputtered-on or otherwise applied layers of the aforementioned materials.

Any combination of the aforementioned materials may also be embedded between the layers.

According to the invention, the above-described wastes in the form of multilayer composite materials, for example especially semiconductor-containing multilayer systems, such as photovoltaic modules, are thus surprisingly separated by a precise cutting with water (an addition of abrasive is not necessary, this would also contaminate the products, which is undesirable) with simultaneous lifting of the cut layer(s) from the soft side in the direction of the carrier layer, e.g. glass.

For this purpose, water is fed by means of a high-pressure pump into a nozzle head, which carries at least one pair of nozzles that direct the individual water jets onto the material to be treated. The nozzle head is brought into rotation and the material to be treated is passed under the rotating nozzle head or the nozzle head is moved over the material.

Depending on the nature of the multilayer to be treated and on the number of individual layers, a certain deviation of the jet angle from 90° in relation to the surface of the multilayer composite is more favorable for the separation effect.

It has proved particularly advantageous for the waterjet treatment to be carried out in strips and for the material to be treated to be continuously scanned.

Alternatively, it makes sense to arrange as many nozzle heads as are necessary so that, based on their respective working width, the total width of the material to be treated can eventually be covered.

The substrate base (carrier layer) thus freed of all layers, in the case of photovoltaic modules simply the glass pane or a plastic pane or layer, can then be dried if necessary by means of a rubber lip or air blower and can leave the plant for stacking in racks or on pallets or for container throwing.

The individualized parts of the structure are discharged from the plant through water curtains from the walls into a water-conducting channel under flow and fed to a solid/liquid separation.

The water is treated for reuse or discarded.

The collected radiated particles can now be homogenized by further crushing in such a way that a simple density separation or, depending on the type of waste, a light chemical treatment can be carried out afterwards.

The layer/value materials made of semiconductor material and/or metal and/or metal alloy, in the example for photovoltaic modules the silicon cell fragments with contacting, which was previously encapsulated between two layers, is now present individually and/or freely accessible at the separated layers.

By using a suitable sorting technology, it is now even possible to sort different plastic films, for example EVA and Tedlar, in the simplest way via density separation and thus generate secondary raw materials of the highest quality. The entire process runs fully automatically.

Preferably, the separation process is carried out by means of water for separating multilayer composite materials, in particular photovoltaic modules, TFT, OLED or LCD displays, in that the material to be separated with individual water jets generates the rapid alternation of the cutting jet and the lifting jet by means of a rotation and a simultaneous feed, thereby separating individual layers down to the substrate.

Typical water pressures are in the range between 750 and 3000 bar or higher.

Advantageously, the rotation speed, number, angles and feed rate are adapted to the material to be processed in such a way that the individual layers are split and cut until the last layer has been removed from the substrate carrier material, e.g. glass, and the substrate appears free of residue.

Preferably, the relative speed between the nozzle head and the material to be processed is between 200 mm/s and 1 mm/s, depending on the separation task. The speed of the nozzle head is between 200/min and 2000/min. Between 10 and 100 l/min of water are required, which is significantly influenced by the number of nozzles used. The following parameters have proven to be particularly advantageous for the typical layer structure of a photovoltaic module consisting of glass, EVA, silicon cells with busbars, EVA and Tedlar: Speed of the nozzle head with 3 pairs of nozzles of 1500 revolutions per minute and a relative speed (feed of the photovoltaic module) of 50 mm/s at 1600 bar. Preferably, the water pressure required to destroy the composite is produced by a high-pressure pump.

Advantageously, the treatment can be carried out horizontally or vertically, depending on the plant design.

The valuable materials, which are now freely accessible, can be recycled further using various treatment methods, for example hydrometallurgical according to DE102014102389A1.

By selectively using multiple nozzles to perform a rotation and sending individual jets of water at high pressure onto a moving multilayer system with a harder base in this process, complete separation of the multilayer system was surprisingly observed with large-area treatment.

This new universal method overcomes the disadvantages of previously used methods, namely the limitation to classical comminution at the cost of losing the semiconductor layers, the complex glass/plastic/metal flake separation from liquids or the complete heating of the entire material.

The method is also ecologically superior to other separation processes due to the mere use of water, which can be reused.

The pressure of the water jet(s) is adjusted in such a way that the softer layers are reliably separated, but the harder substrate or the hard carrier layer are not separated by the water jet(s).

This can be determined by reference tests, for example.

### BRIEF DESCRIPTION OF THE DRAWINGS

The invention is explained in more detail below with reference to exemplary embodiments and associated drawings, without being limited thereto, wherein:

FIG. 1 the basic procedure for separating a multilayer composite material in the form of a photovoltaic module PV,

FIG. 2 shows the schematic representation of a nozzle head DK whose axis of rotation L is arranged perpendicular to the surface O of the multilayer composite material with two nozzles D1, D2 inserted at an angle α,

FIG. 3 shows the schematic representation of a nozzle head DK, which is inclined with its axis of rotation L at an angle β to the surface O of the multilayer composite material and has two mutually parallel nozzles D1, D2,

FIG. 4 shows the schematic representation of a nozzle head DK, the axis of rotation L of which is arranged perpendicular to the surface O of the multilayer composite material with two mutually parallel nozzles D1, D2.

### DETAILED DESCRIPTION OF THE PREFERRED EMBODIMENTS

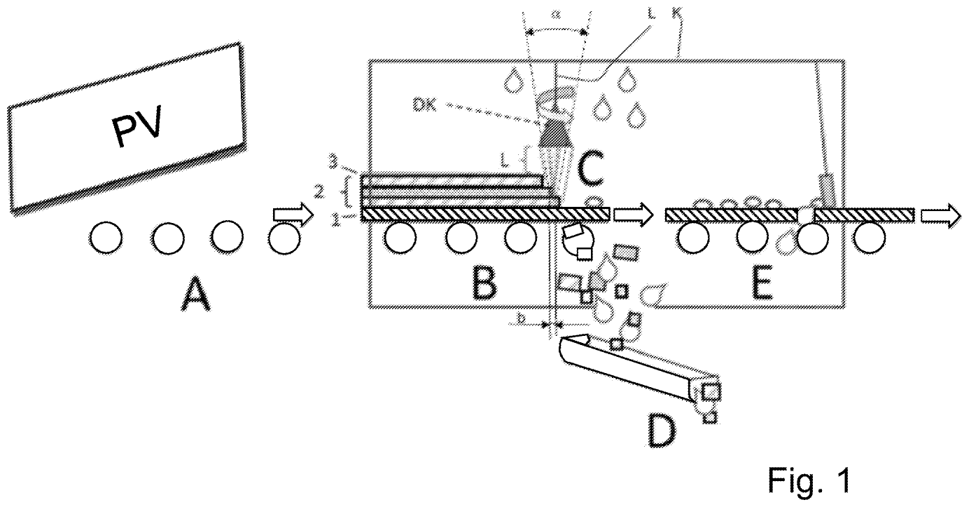

FIG. 1 shows the basic procedure for separating a multilayer composite material in the form of a photovoltaic module PV.

The first layer 1, which is the lower one here, in the form of a carrier layer of the photovoltaic module PV, usually consists of a harder carrier layer in the form of a glass pane of safety glass or also a plastic pane.

Above this are two layers 2 made of a softer material compared to the lower layer 1. The layers 2 can be the plastic films, such as EVA, and/or functional materials, such as silicon cells. The rear layer 3, which is the upper one here, consists of one or more plastic or metal foils.

In a first step A, the photovoltaic module PV is fed to a corresponding device and moved under one or more water jet nozzles or a nozzle head DK with several water jet nozzles not specified here. In a further step B, the waterjet treatment of the photovoltaic module PV takes place through the nozzles of the nozzle head DK, which preferably moves with a uniform relative movement under the nozzles of the nozzle head DK. In this process, one layer 2, 3 after the other is successively cut and removed (see C) until the lower layer 2 alone remains. In a step D, the lower layer 1—glass pane or plastic pane (carrier layer/substrate support)—is then removed and sorted accordingly.

The detached particles are transported out of the plant in the water flow (E) and, if necessary, dewatered.

It can be seen from FIG. 1 that the relative movement first separates and detaches the upper layer 3, then the upper layer 2 offset to it, then again somewhat offset to it the layer 2 below it.

The two nozzles are arranged in the nozzle head DK in such a way that the emerging water jets face each other in the direction of the multilayer composite material. The two water jets preferably impinge on the substrate surface at a distance b apart.

The nozzles arranged outside the axis of rotation L of the nozzle head DK describe a circular rotary motion when the nozzle body DK rotates. This causes the individual layers 2 and 3 to be separated and lifted off piece by piece in a crescent shape from the respective layers below.

The valuable materials that were located between the layers, such as semiconductor material and optionally other metals and/or alloys of the layers, are now freely accessible in the mixture of the detached layers 2 and can now be separated, dissolved and recovered by means of conventional processes (as well as possibly the existing metals and/or alloys of, for example, contacts and conductor tracks).

In tests, for example, whole solar modules with and without frames were used. The material, as an example of a multilayer system, consisted of front glass (lower layer 1) and a structure (foil, silicon cell with interconnecting conductors, foil, back foil)=layers 2 and 3.

By means of the rotating nozzle head DK, which had a working width of 25 cm, the photovoltaic modules were driven over the entire surface. The water pressure used was between 750 and 2000 bar, depending on the module type. The multilayer structure was cut sharply on the aluminum frame and completely removed from the glass—the lower layer 1 (carrier layer).

The lower harder layer 1 in the form of the carrier material is thus not cut by water jet, but only the layers arranged thereon are removed or detached and crushed.

The blasting material, a mixture of the shredded individual layers 2, 3 and the valuable materials that were between the layers, such as broken silicon cells, tinned copper strips, EVA and Tedlar foil, are now collected and sent for further recycling.

The glasses (carrier layer, layer 1) with frame were dropped onto a grate equipped with thorns, whereupon the glass shattered, fell through the grate into a container and the frame, as well as the can with the cables, remained on the grate. Both could now be placed in the respective collection containers for metal recycling.

The distance of the nozzle head DK to the substrate to be treated (photovoltaic module PV was 4 cm, the water consumption was on average 30 l/min).

Overall, the present invention is the first to provide a method for separating or unraveling large-area multilayer composite materials (composite materials or multilayer systems) using only water as a tool without chemical additives.

The upper layers can be shredded and lifted from each other, sorted and also fed into a recycling process as valuable materials.

The now exposed valuable materials that were located between the layers 2, such as semiconductors and/or metals or metal alloys, can also be recovered. The carrier layer 1 and/or the back layer 3 as well as the layers 2 can also be recycled as valuable materials.

The glass cullet produced in this way (the lower carrier layer/layer 1 in FIG. 1) is highly pure and represents a sought-after cullet as a secondary raw material in the glass industry, with the sum of the minor constituents being less than 0.7%. The following Table 1 illustrates this:

TABLE 1
Composition of the recycled glass produced, main components.

| Glass analyses | | | |
|---|---|---|---|
| by means of | Module 1 | Module 2 | Module 3 |
| Al₂O₃ [%] | 0.622 | 0.712 | 0.804 |
| Fe₂O₃ [%] | 0.067 | 0.073 | 0.047 |
| CaO [%] | 8.83 | 9.11 | 9.29 |
| MgO [%] | 4.45 | 4.11 | 3.95 |
| Na₂O [%] | 13.67 | 13.36 | 13.47 |
| SiO₂ [%] | 71.79 | 71.96 | 71.79 |

The process parameters in the form of nozzle head speed and/or feed rate and/or relative speed and/or water pressure, angle of attack and/or number of nozzles can be determined in reference tests.

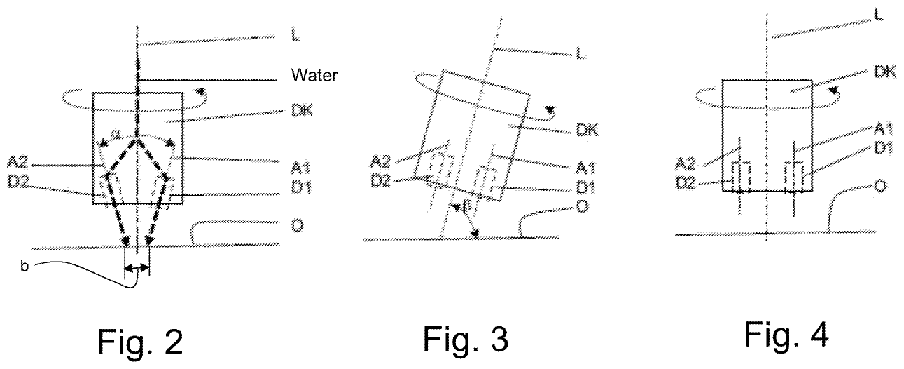

Variants of the design and orientation of the nozzle head DK and here, for example, of two nozzles D1 and D2 inserted therein are shown in FIGS. 2 to 4.

FIG. 2 shows the schematic representation of a nozzle head DK, the axis of rotation L of which is arranged perpendicular to the surface O of the multilayer composite material. Two nozzles D1 and D2 are inserted into the nozzle body, the longitudinal axes A1 and D2 of which are inclined at an angle α to one another. The angle bisector lies here on the longitudinal axis L of the nozzle head DK, the thick dashed line illustrates the guidance of the water supplied under pressure, wherein the water supplied via a pressure line not shown is divided in the nozzle head between the two nozzles D1, D2 so that two water jets emerge. These meet the surface O of the multilayer composite material at a distance b apart.

FIG. 3 shows the schematic representation of a nozzle head DK, which is inclined with its axis of rotation L at an angle β to the surface O of the multilayer composite material and has two mutually parallel nozzles D1, D2, which thus have the same angle β to the surface O.

It is also possible with an inclined nozzle body according to an example not shown to additionally arrange the nozzles D1, D2 at an angle α to each other as in FIG. 2.

FIG. 4 shows the schematic representation of a nozzle head DK, the axis of rotation L of which is arranged perpendicular to the surface O of the multilayer composite material with two mutually parallel D1, D2.

It is also possible, according to variants not shown, to use in a nozzle head one or more nozzles whose longitudinal axes are parallel to the axis of rotation L and to combine this with one or more nozzles whose longitudinal axes are at an angle to the axis of rotation L of the nozzle head DK.

Furthermore, it is possible, for example, to provide two or more nozzle heads D1, D2, which are identical or different in their structural design.

For example, in a nozzle head DK only one nozzle can be inserted, the longitudinal axis of which is spaced from the axis of rotation of the nozzle head, and two of these nozzle heads rotate in pairs next to each other. The orientation of the nozzles in the nozzle heads can be the same or different.

Furthermore, the nozzle heads DK can be inclined to each other in such a way that the water jets emerging from the nozzles D1, D2 face each other at an angle (similar to FIG. 2).

Due to the nozzles rotating around the axis of rotation L of the nozzle head DK, a circular cutting path is realized.

In particular, the inclined position of the nozzles and/or the nozzle head after cutting the layers causes them to be lifted off the respective underlying layer.

In this process, the rotation and the simultaneous feed cause the quick change of the cutting jet and the lifting jet.

The jet that strikes first in the direction of rotation thus cuts the respective layer, and the jet that follows in the direction of rotation lifts the separated part of the layer from its substrate.

As a result, the individual layers are separated into individual parts or sections and lifted off, thereby separating them down to the base.

As previously described, the layer-by-layer and piece-by-piece separation and lifting of the layers gently exposes the materials in between.

The invention thus provides a simple and efficient solution for separating composite materials or multilayer systems, in which valuable materials on the inside, such as semiconductor materials and/or metals, or also inorganic or organic materials, with which layers of a multilayer system can be formed, are made available for further utilization/recycling, although the hard carrier layer is retained.

Both the carrier layer/layer 1 and the sections of the shredded layers 2, 3 can also be recycled as valuable materials.

1.-16. (canceled)

17. A method for separating multilayer composite material, in particular in the form of photovoltaic modules (PV), TFT, OLED or LCD displays, in which valuable materials are located between layers of the multilayer composite material, consisting of at least one lower layer (1) in the form of a carrier layer and at least one softer layer (2, 3) located thereon, characterized in that one or more layers (2, 3) of the multilayer composite material to be separated are cut and lifted off and individualized in layers or completely by at least one high-pressure water jet, wherein at least one nozzle head (DK) has a nozzle (DK) arranged outside the axis of rotation of the nozzle head (DK) and one or more nozzles (D1, D2) emitting the high-pressure water jet rotate about an axis of rotation (L) of the nozzle head (DK) by means of a rotatable nozzle head (DK), with simultaneous relative movement between the nozzle head (DK) and the multilayer composite material, so that, after separation, the valuable materials are exposed individually or at the separated layers (1, 2, 3) and at least the valuable materials which were located between layers (1, 2, 3) are recycled after separation, and wherein the waterjet treatment is carried out in strips according to the working width of the nozzle head (DK) and the multilayer composite material to be treated is either scanned or, in the case of linear pass, several nozzle heads (DK) are installed next to one another according to the width of the multilayer composite material to be treated.

18. The method according to claim 17, characterized in that a separation process of the multilayer composite material is carried out in that at least two nozzles arranged in pairs cut through one or more layers (2, 3) by a rotation with simultaneous advancement of the material to be treated or of the nozzle head (DK) itself and lifting off the cut portions and cleaning the lower layer (1) simultaneously.

19. The method according to claim 17, characterized in that the feed rate is designed such that the layers (2, 3) of the material to be separated are each penetrated and, by means of a suitable jet angle (a) of the nozzles (D1, D2), this material is lifted from its substrate and thus loosened.

20. The method according to claim 17, characterized in that the pressure necessary for the destruction and thus the separation of the composite of the multilayer composite material is provided between 750 and 3000 bar.

21. The method according to claim 17, characterized in that the rotational speed of the nozzle head (DK) is adapted to the respective feed rate in such a way that cutting and lifting for the respective number of individual layers (2, 3) takes place successively.

22. The method according to claim 17, characterized in that the material of the layer(s) (2, 3) to be separated with individual water jets by a rotation of the nozzle head (DK) and simultaneous feed generates a rapid change of a cutting jet and a lifting jet and thereby individual layers are separated down to the carrier layer in the form of the lower layer (1).

23. The method according to claim 17, characterized in that the nozzle (D1, D2) leading in one direction of rotation cuts the layer (2, 3) on which its water jet impinges, and in that the water jet of the nozzle (D1, D2) following in the direction of rotation lifts the cut-off part of the layer(s) (2, 3).

24. The method according to claim 17, characterized in that the individual layers (2, 3) detached from the lower layer (1) by the water jets are rinsed off together by means of water curtains from the walls of a blasting cabinet and flushed out in a channel from a steel cabinet (K).

25. The method according to claim 17, characterized in that the nozzles (D1, D2) and or nozzle heads (DK) are adapted with respect to A) jet shape, B) angle and C) number so that by A) the penetration depth, B) the lift-off and C) the working speed and/or the shape of the cut fragments can be adjusted.

26. A device for carrying out the method according to claim 17 for separating multilayer composite material in which valuable material is interposed between layers of the multilayer composite material, characterized in that at least one nozzle (D1, D2) is provided for emitting in each case at least one high-pressure water jet, wherein at least one nozzle head (DK) has a nozzle (DK) arranged outside the axis of rotation of the nozzle head (DK).

27. The device according to claim 26, characterized in that at least two nozzles (D1, D2) are provided for emitting at least one high-pressure water jet each, and in that the nozzles (D1, D2) are arranged such that the high-pressure water jets impinging on the surface of the multilayer composite material are spaced apart from each other.

28. The device according to claim 26, characterized in that at least two nozzles are arranged in a nozzle head (DK) rotatable about an axis of rotation (L) or in two separate nozzle heads (DK), wherein the water jets emerging from the nozzles (D1, D2) face each other.

29. The device according to claim 26, characterized in that the at least one nozzle head (DK), which has at least two nozzles (D1, D2), is installed at a distance (L) from the upper side of the multilayer composite material which ensures a spacing (b) of the water jets impinging on the upper side of the multilayer composite material when the nozzles (D1, D2) are arranged inclined at an angle (α) to one another in the nozzle head (DK).

30. The device according to claim 26, characterized in that at least two nozzle heads (DK), each having at least one nozzle (D1, D2), are installed at a distance (L) from the upper side of the multilayer composite material, which distance (L) ensures a spacing (b) of the water jets impinging on the upper side of the multilayer composite material when the nozzle (D1, D2) of the nozzle heads (DK) is arranged inclined at an angle (α) to one another.

31. The device according to claim 26, characterized in that at least one nozzle (D1, D2) cuts the layer(s) (2, 3) and at least one further nozzle (1, 2) lifts and individualizes the cut-off part of the layer(s) (2, 3).
